(19) United States
(12) Patent Application Publication
(10) Pub. No.: US 2024/0282598 A1
(43) Pub. Date: Aug. 22, 2024

(54) SUBSTRATE PROCESSING APPARATUS AND SUBSTRATE PROCESSING METHOD

(71) Applicant: Tokyo Electron Limited, Tokyo (JP)

(72) Inventor: Hiroshi MARUMOTO, Kumamoto (JP)

(73) Assignee: Tokyo Electron Limited, Tokyo (JP)

(21) Appl. No.: 18/429,479

(22) Filed: Feb. 1, 2024

(30) Foreign Application Priority Data
Feb. 20, 2023 (JP) 2023-023938

(51) Int. Cl. H01L 21/67; H01L 21/66

(52) U.S. Cl. CPC H01L 21/6708; H01L 21/67248; H01L 22/12

(57) ABSTRACT

The substrate processing unit processes a substrate, by generating a mixed solution by mixing a first processing liquid and a second processing liquid, and by supplying the mixed solution to the substrate. The first opening/closing valve opens and closes the first route for supplying the first processing liquid. The second opening/closing valve opens and closes the second route that supplies the second processing liquid. The temperature detection unit is provided on at least one of the first route and second route, and detects temperature of the processing liquid. The controller determines whether the temperature of the processing liquid is within an allowable range, before the supply of the mixed solution to the substrate is started. The controller starts supplying the mixed solution to the substrate by opening the first opening/closing valve and the second opening/closing valve, when the temperature of the processing liquid is within the allowable range.

### CROSS-REFERENCE TO RELATED APPLICATION

The present application claims priority to and incorporates by reference the entire contents of Japanese Patent Application No. 2023-023938 filed in Japan on Feb. 20, 2023.

### FIELD

Exemplary embodiments disclosed herein relate to a substrate processing apparatus and a substrate processing method.

### BACKGROUND

Conventionally, a substrate processing apparatus is known to process a substrate such as a semiconductor wafer and a glass substrate, using a mixed solution of a first processing liquid and a second processing liquid.
Patent Literature 1: Japanese Laid-open Patent Publication No. 2018-56293

The present disclosure provides a technique capable of suppressing variations in the processing results of the substrates in substrate processing using a mixed solution.

### SUMMARY

A substrate processing apparatus according to one aspect of the present disclosure includes: a substrate processing unit that processes a substrate, by generating a mixed solution by mixing a first processing liquid and a second processing liquid, and by supplying the generated mixed solution to the substrate; a first route that supplies the first processing liquid to the substrate processing unit; a second route that supplies the second processing liquid to the substrate processing unit; a first opening/closing valve that opens and closes the first route; a second opening/closing valve that opens and closes the second route; a temperature detection unit provided on at least one of the first route and the second route, and that detects temperature of a processing liquid in at least one of the routes; and a controller that controls each unit, wherein the controller determines whether the temperature of the processing liquid detected using the temperature detection unit is within an allowable range, before the substrate processing unit starts supplying the mixed solution to the substrate, and when the temperature of the processing liquid is within the allowable range, starts supplying the mixed solution to the substrate by opening the first opening/closing valve and the second opening/closing valve.

### BRIEF DESCRIPTION OF DRAWINGS

FIG. 1 is a diagram illustrating a schematic configuration of a substrate processing system according to a first embodiment;

FIG. 2 is a diagram illustrating a configuration of a processing unit according to the first embodiment;

FIG. 3 is a diagram illustrating a specific configuration example of a processing liquid supply system in the substrate processing system according to the first embodiment;

FIG. 4 is a flowchart illustrating an example of a procedure of substrate processing performed by a processing unit according to the first embodiment;

FIG. 5 is a flowchart illustrating a procedure of an SPM supply process according to the first embodiment;

FIG. 6 is a diagram illustrating a specific configuration example of a processing liquid supply system in a substrate processing system according to a second embodiment;

FIG. 7 is a flowchart illustrating a specific procedure of an SPM supply process according to the second embodiment; and

FIG. 8 is a diagram illustrating a specific configuration example of a processing liquid supply system in a substrate processing system according to a third embodiment.

### DESCRIPTION OF EMBODIMENTS

Hereinafter, modes (hereinafter, referred to as “embodiments”) for a substrate processing apparatus and a substrate processing method of the present disclosure will be described in detail with reference to the accompanying drawings. However, the present disclosure is not limited to the exemplary embodiments.

Moreover, in the embodiments described below, expressions such as “constant”, “orthogonal”, “vertical”, or “parallel” may be used. However, these expressions do not need to be exactly “constant”, “orthogonal”, “vertical”, or “parallel”. That is, for example, each of the above expressions allows deviations in manufacturing accuracy, installation accuracy, and the like.

Moreover, in each of the drawings referred to below, for ease of explanation, an X-axis direction, a Y-axis direction, and a Z-axis direction that are orthogonal to each other may be defined to illustrate an orthogonal coordinate system in which the Z-axis positive direction is the vertically upward direction.

Conventionally, a substrate processing apparatus is known to process a substrate such as a semiconductor wafer and a glass substrate, using a mixed solution of a first processing liquid and a second processing liquid. For example, the mixed solution includes a Sulfuric acid Hydrogen Peroxide Mixture (SPM) that is a mixed solution of sulfuric acid and hydrogen peroxide solution and the like.

However, in the substrate processing using a mixed solution, due to variations in the temperature of the mixed solution supplied to the substrate, the processing results of the substrates may vary. That is, the first processing liquid and the second processing liquid before being mixed are retained in each supply route of the first processing liquid and the second processing liquid during a period when the substrate processing using a mixed solution is not taking place. With an increase in the retention time in the supply route, the temperature of the first processing liquid and the second processing liquid before being mixed is lowered. Consequently, temperature variations occur on the first processing liquid and the second processing liquid before being mixed. Hence, when producing a mixed solution, temperature variations occur on the generated mixed solution. As a result, in the substrate processing using a mixed solution, due to variations in the temperature of the mixed solution, the processing results of the substrates may vary.

Therefore, a technique capable of suppressing variations in the processing results of the substrates in the substrate processing using a mixed solution has been sought after.

### First Embodiment

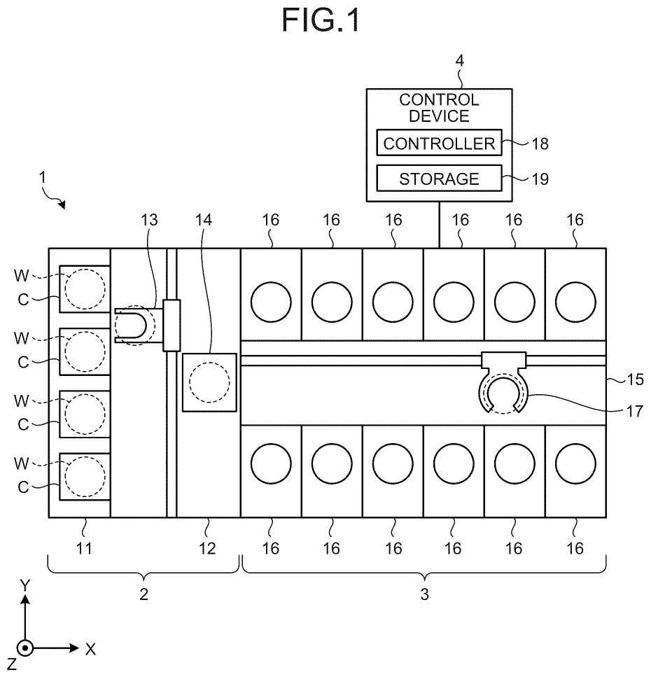

A schematic configuration of a substrate processing system 1 (an example of a substrate processing apparatus) according to the first embodiment will be described with reference to FIG. 1. FIG. 1 is a diagram illustrating a schematic configuration of the substrate processing system 1 according to the first embodiment.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a carrier placing section 11 and a transfer section 12. A plurality of carriers C that accommodate a plurality of substrates, in the embodiments, semiconductor wafers W (hereinafter, referred to as wafers W) in a horizontal state are placed on the carrier placing section 11.

The transfer section 12 is provided adjacent to the carrier placing section 11, and includes a substrate transfer device 13 and a delivery unit 14 therein. The substrate transfer device 13 has a wafer holding mechanism to hold each of the wafers W. Moreover, the substrate transfer device 13 can move in a horizontal direction and a vertical direction, and can rotate around a vertical axis. The substrate transfer device 13 transfers the wafer W between the carrier C and the delivery unit 14 using the wafer holding mechanism.

The processing station 3 is provided adjacent to the transfer section 12. The processing station 3 includes a transfer section 15 and a plurality of processing units 16 (an example of substrate processing units). The processing units 16 are provided side by side on both sides of the transfer section 15.

The transfer section 15 includes a substrate transfer device 17 therein. The substrate transfer device 17 has a wafer holding mechanism to hold each of the wafers W. Moreover, the substrate transfer device 17 can move in the horizontal direction and the vertical direction, and can rotate around the vertical axis. The substrate transfer device 17 transfers the wafer W between the delivery unit 14 and the processing unit 16 using the wafer holding mechanism.

The processing unit 16 performs predetermined substrate processing on the wafer W transferred by the substrate transfer device 17.

Moreover, the substrate processing system 1 includes a control device 4. For example, the control device 4 is a computer, and includes a controller 18 and a storage 19. The storage 19 stores a computer program that controls various types of processing performed in the substrate processing system 1. The controller 18 controls the operation of the substrate processing system 1, by reading and executing the computer program stored in the storage 19.

The computer program may be recorded on a computer-readable storage medium, or may be installed in the storage 19 of the control device 4 from the storage medium. For example, the computer-readable storage medium includes a hard disk (HD), a flexible disk (FD), a compact disc (CD), a magnet optical disk (MO), a memory card, and the like.

In the substrate processing system 1 configured as described above, first, the substrate transfer device 13 of the carry-in/out station 2 takes out the wafer W from the carrier C placed in the carrier placing section 11, and places the wafer W on the delivery unit 14. The wafer W placed on the delivery unit 14 is taken out from the delivery unit 14 by the substrate transfer device 17 of the processing station 3, and is transferred to the processing unit 16.

On the wafer W transferred to the processing unit 16, substrate processing is performed by the processing unit 16. Then, the wafer W is carried out from the processing unit 16 by the substrate transfer device 17, and is placed on the delivery unit 14. Then, the processed wafer W placed on the delivery unit 14 is returned to the carrier C in the carrier placing section 11 by the substrate transfer device 13.

The controller 18 of the control device 4 includes a microcomputer including a Central Processing Unit (CPU), a Read Only Memory (ROM), a Random Access Memory (RAM), an input/output port, and the like, and various types of circuits. The CPU of the microcomputer reads and executes a computer program stored in the ROM to implement the following control. Moreover, for example, the storage 19 is implemented by a semiconductor memory element such as a RAM and a flash memory, or a storage device such as a hard disk and an optical disc.

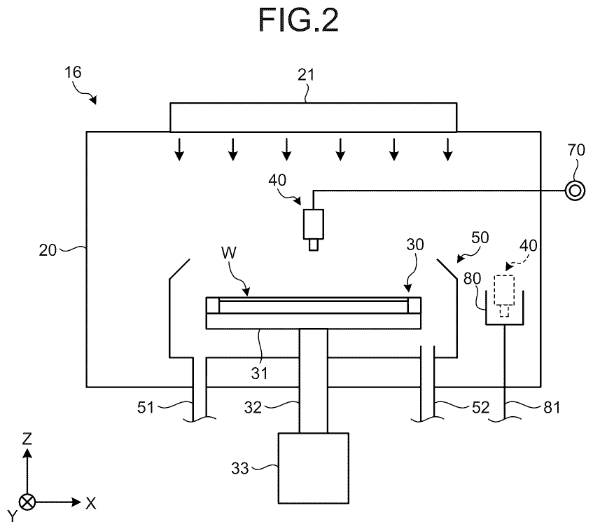

Next, a configuration of the processing unit 16 will be described with reference to FIG. 2. FIG. 2 is a diagram illustrating a configuration of the processing unit 16 according to the first embodiment.

As illustrated in FIG. 2, the processing unit 16 includes a chamber 20, a substrate holding mechanism 30, a nozzle 40, a recovery cup 50, and an accommodation unit 80. The chamber 20 accommodates the substrate holding mechanism 30, the nozzle 40, and the recovery cup 50. A Fan Filter Unit (FFU) 21 is provided on the ceiling of the chamber 20. The FFU 21 forms a down flow in the chamber 20.

The substrate holding mechanism 30 includes a holding unit 31, a supporting unit 32, and a driving unit 33. The holding unit 31 holds the wafer W horizontally. The supporting unit 32 is a member extending in the vertical direction. The bottom end of the supporting unit 32 is rotatably supported by the driving unit 33, and the leading end of the supporting unit 32 horizontally supports the holding unit 31. The driving unit 33 rotates the supporting unit 32 around the vertical axis. The substrate holding mechanism 30 rotates the holding unit 31 supported by the supporting unit 32, by rotating the supporting unit 32 using the driving unit 33. Consequently, the substrate holding mechanism 30 rotates the wafer W held by the holding unit 31.

The nozzle 40 supplies processing liquid to the wafer W. The nozzle 40 is connected to a processing liquid supply source 70. The nozzle 40 is supported horizontally by an arm, which is not illustrated. The arm is turned, lifted, or lowered by a turning/lifting mechanism, which is not illustrated.

The recovery cup 50 is disposed so as to surround the holding unit 31, and collects the processing liquid scattered from the wafer W by the rotation of the holding unit 31. A drain port 51 is formed on the bottom of the recovery cup 50, and the processing liquid collected by the recovery cup 50 is discharged to the outside of the processing unit 16 through the drain port 51. Moreover, an exhaust port 52 that discharges gas supplied from the FFU21 to the outside of the processing unit 16 is formed on the bottom of the recovery cup 50.

For example, the accommodation unit 80 is disposed outside the recovery cup 50. When the nozzle 40 is not discharging the processing liquid on the wafer W, the accommodation unit 80 accommodates the nozzle 40 to standby. Then, while the nozzle 40 is standing by in the accommodation unit 80, a dummy dispensing process is performed. For example, the dummy dispensing process is a process of suitably discharging the processing liquid from the nozzle 40, while the nozzle 40 is standing by and is not discharging the processing liquid to the wafer W, to prevent deterioration of the processing liquid. The processing liquid discharged from the nozzle 40 is discharged to the outside through a discharge route 81.

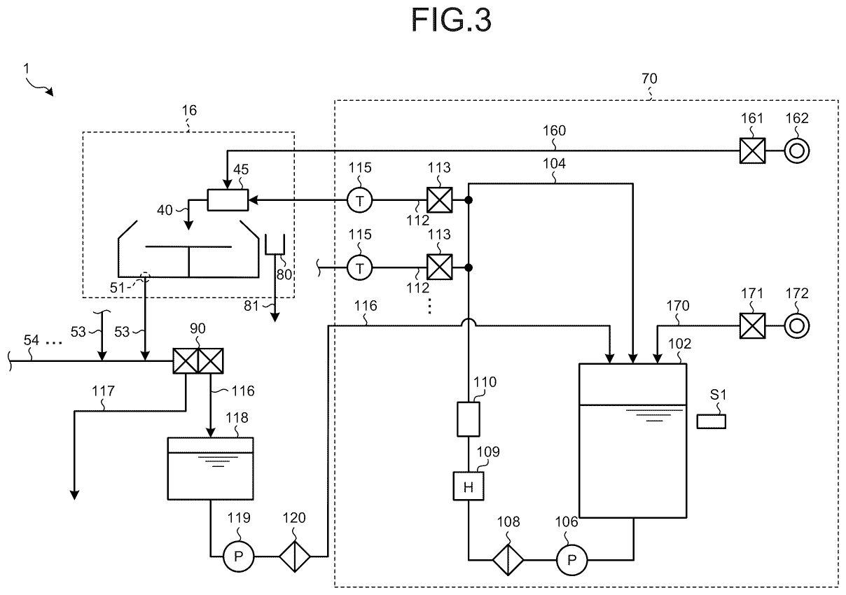

Next, a specific configuration of the processing liquid supply system in the substrate processing system 1 according to the first embodiment will be described with reference to FIG. 3. FIG. 3 is a diagram illustrating a specific configuration example of a processing liquid supply system in the substrate processing system 1 according to the first embodiment.

Hereinafter, a configuration example of the processing liquid supply system in which sulfuric acid is used as the first processing liquid and a hydrogen peroxide solution is used as the second processing liquid, and when the SPM that is a mixed solution of sulfuric acid and hydrogen peroxide solution is supplied to the wafer W will be described.

As illustrated in FIG. 3, as a supply system of sulfuric acid, the processing liquid supply source 70 includes a retaining tank 102, a circulation route 104, and a plurality of branch routes 112 (an example of first routes). The retaining tank 102 retains sulfuric acid. The circulation route 104 extends from the retaining tank 102 and returns back to the retaining tank 102. The branch routes 112 are branched from the circulation route 104 and are connected to each processing unit 16.

The retaining tank 102 includes a liquid level sensor S1. For example, the liquid level sensor S1 is disposed beside the retaining tank 102, and detects the liquid level of sulfuric acid retained in the retaining tank 102. Specifically, the liquid level sensor S1 is a sensor for detecting the lower limit liquid surface in the retaining tank 102. The detection results of the liquid level sensor S1 are output to the controller 18.

In the circulation route 104, a pump 106, a filter 108, a heater 109, and a densitometer 110 are sequentially provided from the upstream side. The pump 106 forms a circulating flow from the retaining tank 102, through the circulation route 104, and back to the retaining tank 102. The filter 108 removes contaminants such as particles in the sulfuric acid. The heater 109 is controlled by the controller 18, and heats the sulfuric acid circulating in the circulation route 104 to a set temperature. The densitometer 110 detects the concentration of sulfuric acid circulating in the circulation route 104, and outputs the detection results to the controller 18.

The branch routes 112 are connected to the circulation route 104 on the downstream side of the densitometer 110. Each of the branch routes 112 is connected to a mixing unit 45, which will be described below, in each processing unit 16, and supplies the sulfuric acid flowing through the circulation route 104 to each mixing unit 45. In each branch route 112, a valve 113 (an example of a first opening/closing valve) and a temperature detection unit 115 are sequentially provided from the upstream side. The valve 113 opens and closes each branch route 112. The temperature detection unit 115 detects the temperature of the sulfuric acid in the branch route 112. Specifically, the temperature detection unit 115 detects the temperature of the sulfuric acid flowing through the branch route 112, or the sulfuric acid retained in the branch route 112. The detection results by the temperature detection unit 115 are output to the controller 18.

Moreover, as a supply system of hydrogen peroxide solution, the processing liquid supply source 70 includes a hydrogen peroxide solution supply route 160 (an example of a second route), a valve 161 (an example of a second opening/closing valve), and a hydrogen peroxide solution supply source 162. One end of the hydrogen peroxide solution supply route 160 is connected to the hydrogen peroxide solution supply source 162 via the valve 161, and the other end is connected to the mixing unit 45, which will be described below, of the processing unit 16. The processing liquid supply source 70 supplies the hydrogen peroxide solution supplied from the hydrogen peroxide solution supply source 162 to the mixing unit 45 of the processing unit 16 via the hydrogen peroxide solution supply route 160.

Although not illustrated in this example, another temperature detection unit may also be provided in the hydrogen peroxide solution supply route 160. The other temperature detection unit detects the temperature of the hydrogen peroxide solution in the hydrogen peroxide solution supply route 160. Specifically, the other temperature detection unit detects the temperature of the hydrogen peroxide solution flowing through the hydrogen peroxide solution supply route 160, or the hydrogen peroxide solution retained in the hydrogen peroxide solution supply route 160. The detection results by the other temperature detection unit are output to the controller 18.

Moreover, the processing liquid supply source 70 includes a supply route 170, a valve 171, and a sulfuric acid supply source 172. One end of the supply route 170 is connected to the sulfuric acid supply source 172 via the valve 171, and the other end is connected to the retaining tank 102. The sulfuric acid supply source 172 supplies sulfuric acid. The processing liquid supply source 70 supplies the sulfuric acid supplied from the sulfuric acid supply source 172 to the retaining tank 102 via the supply route 170.

Although not illustrated in this example, the processing liquid supply source 70 includes a rinsing solution supply route for supplying a rinsing solution to the processing unit 16. For example, deionized water (DIW) can be used as a rinsing solution.

The processing unit 16 includes the mixing unit 45. The mixing unit 45 generates the SPM that is a mixed solution of the sulfuric acid supplied from the branch route 112 and the hydrogen peroxide solution supplied from the hydrogen peroxide solution supply route 160, and supplies the generated SPM to the nozzle 40. The mixing unit 45 may also be integrally incorporated into the nozzle 40.

Moreover, the drain port 51 of each processing unit 16 is connected to a discharge route 54 via a branch route 53. The SPM used in each processing unit 16 is discharged from the drain port 51 to the discharge route 54 through the branch route 53.

In this example, the SPM and the rinsing solution are supplied using the nozzle 40. However, the processing unit 16 may also include a separate nozzle for supplying the rinsing solution.

The substrate processing system 1 further includes a switching unit 90, a collection route 116, and a disposal route 117. The switching unit 90 is connected to the discharge route 54, the collection route 116, and the disposal route 117, and under the control of the controller 18, switches the flowing destination of the used SPM flowing through the discharge route 54 between the collection route 116 and the disposal route 117.

One end of the collection route 116 is connected to the switching unit 90, and the other end is connected to the retaining tank 102. In the collection route 116, a collection tank 118, a pump 119, and a filter 120 are sequentially provided from the upstream side. The collection tank 118 temporarily retains the used SPM. The pump 119 forms a flow of sending the used SPM retained in the collection tank 118 to the retaining tank 102. The filter 120 removes contaminants such as particles in the used SPM.

The disposal route 117 is connected to the switching unit 90, and discharges the used SPM that flows in from the discharge route 54 via the switching unit 90, to the outside of the substrate processing system 1.

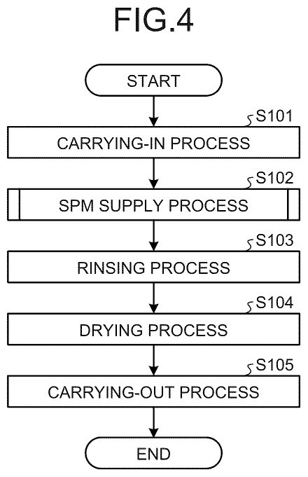

Next, the details of the substrate processing performed by the processing unit 16 according to the present embodiment will be described with reference to FIG. 4. FIG. 4 is a flowchart illustrating an example of a procedure of substrate processing performed by the processing unit 16 according to the first embodiment. Each of the processing procedures illustrated in FIG. 4 is performed under the control of the controller 18.

First, a carrying-in process of the wafer W is performed in the processing unit 16 (step S101). Specifically, the wafer W is carried into the chamber 20 (see FIG. 2) of the processing unit 16 by the substrate transfer device 17 (see FIG. 1), and is held by the holding unit 31. The processing unit 16 then rotates the holding unit 31 at a predetermined rotational speed (for example, 50 rpm).

Subsequently, an SPM supply process is performed in the processing unit 16 (step S102). In the SPM supply process, the SPM is supplied to the upper surface of the wafer W from the nozzle 40, when the valve 113 and the valve 161 are opened for a predetermined time (for example, 30 seconds). The SPM supplied to the wafer W is spread on the top face of the wafer W by the centrifugal force caused by the rotation of the wafer W. Details of the SPM supply process will be described below.

In the SPM supply process, for example, by using the strong oxidizing power of Caro's acid contained in the SPM, and the reaction heat of sulfuric acid and hydrogen peroxide solution, the film formed on the upper surface of the wafer W is etched.

When the SPM supply process at step S102 is finished, a rinsing process is performed in the processing unit 16 (step S103). In the rinsing process, a rinsing solution (for example, DIW) is supplied to the upper surface of the wafer W from a rinsing solution supply unit, which is not illustrated. The DIW supplied to the wafer W is spread on the top face of the wafer W by the centrifugal force caused by the rotation of the wafer W. Consequently, the SPM remaining on the wafer W is washed away by the DIW.

Subsequently, a drying process is performed in the processing unit 16 (step S104). In the drying process, the wafer W is rotated at a predetermined rotational speed (for example, 1000 rpm) for a predetermined time. Consequently, the DIW remaining on the wafer W is shaken off, thereby drying the wafer W. The rotation of the wafer W is then stopped.

Then, a carrying-out process is performed in the processing unit 16 (step S105). In the carrying-out process, the wafer W held by the holding unit 31 is passed to the substrate transfer device 17. When the carrying-out process is completed, substrate processing on one wafer W is completed.

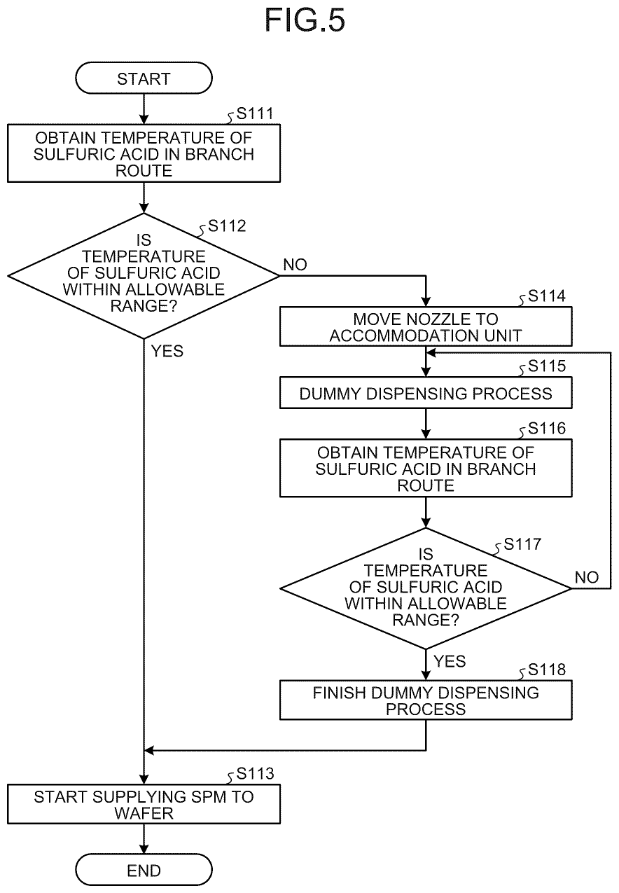

Next, the specific procedure of the SPM supply process at step S102 will be described with reference to FIG. 5. FIG. 5 is a flowchart illustrating a procedure of the SPM supply process according to the first embodiment.

As illustrated in FIG. 5, first, the controller 18 obtains the temperature of the sulfuric acid in the branch route 112 from the temperature detection unit 115 (step S111). Then, the controller 18 determines whether the temperature of the sulfuric acid obtained from the temperature detection unit 115 is within an allowable range (step S112). In this process, for example, the allowable range is a predetermined temperature range around the set temperature of the heater 109 (see FIG. 3). For example, the set temperature of the heater 109 is 45° C.

If the temperature of sulfuric acid is within the allowable range (Yes at step S112), the controller 18 opens the valve 113 and the valve 161, and starts supplying the SPM to the wafer W from the nozzle 40 (step S113). The SPM supplied to the wafer W is generated by mixing the sulfuric acid and hydrogen peroxide solution the temperature of which is within the allowable range. Therefore, it is possible to suppress variations in the temperature of the SPM supplied to the wafer W, and as a result, it is possible to suppress variations in the processing results of the wafers W in the substrate processing using SPM.

On the other hand, if the temperature of sulfuric acid is not within the allowable range (No at step S112), the controller 18 controls the turning/lifting mechanism, which is not illustrated, and moves the nozzle 40 to the accommodation unit 80 to standby (step S114). Then, the controller 18 performs a dummy dispensing process (step S115). In the dummy dispensing process, the controller 18 opens the valve 113 to discharge sulfuric acid into the accommodation unit 80 from the nozzle 40. Consequently, the sulfuric acid that is circulated in the circulation route 104 and the temperature of which is maintained at a set temperature by the heater 109 is supplied to the branch route 112, and the sulfuric acid that is relatively low in temperature retained in the branch route 112 is pushed out to the accommodation unit 80 via the mixing unit 45 and the nozzle 40. Consequently, the temperature of the sulfuric acid in the branch route 112 rises and falls within the allowable range. As a result, it is possible to suppress variations in the temperature of the sulfuric acid before being mixed by the mixing unit 45. The sulfuric acid pushed out to the accommodation unit 80 is discharged to the outside through the discharge route 81.

Subsequently, the controller 18 obtains the temperature of the sulfuric acid in the branch route 112 from the temperature detection unit 115 (step S116). Then, the controller 18 determines whether the temperature of the sulfuric acid obtained from the temperature detection unit 115 is within the allowable range (step S117).

If the temperature of sulfuric acid is not within the allowable range (No at step S117), the controller 18 returns the process to step S115. On the other hand, if the temperature of sulfuric acid is within the allowable range (Yes at step S117), the controller 18 closes the valve 113 and finishes the dummy dispensing process (step S118). Consequently, it is possible to finish the dummy dispensing process at a suitable timing, and suppress the consumption amount of sulfuric acid in the dummy dispensing process. The controller then controls the turning/lifting mechanism, which is not illustrated, and moves the nozzle 40 from the accommodation unit 80 to the processing position above the wafer W, that is, the position where the SPM can be supplied to the wafer W.

Subsequently, the controller 18 opens the valve 113 and the valve 161 and starts supplying the SPM to the wafer W from the nozzle 40 (step S113). The SPM supplied to the wafer W is generated by mixing the sulfuric acid and hydrogen peroxide solution the temperature of which is within the allowable range. Therefore, it is possible to suppress variations in the temperature of the SPM supplied to the wafer W, and as a result, it is possible to suppress variations in the processing results of the wafers W in the substrate processing using SPM.

In the example in FIG. 5, the controller 18 starts supplying the SPM to the wafer W, when the temperature of the sulfuric acid in the branch route 112 is within the allowable range. However, the starting conditions for supplying the SPM are not limited thereto. For example, the controller 18 may also determine whether the temperature of the hydrogen peroxide solution in the hydrogen peroxide solution supply route 160 is within the allowable range, and start supplying the SPM to the wafer W, when the temperature of the hydrogen peroxide solution is within the allowable range. For example, the allowable temperature range of the hydrogen peroxide solution is a predetermined temperature range around the ambient temperature (25° C.). Moreover, for example, the controller 18 may start supplying the SPM to the wafer W, when the temperature of sulfuric acid in the branch route 112 and the temperature of hydrogen peroxide solution in the hydrogen peroxide solution supply route 160 are each within the allowable range.

Furthermore, the processes at steps S111, S112, and S114 to S118 in FIG. 5 may be performed at any time before the controller 18 starts supplying the SPM to the wafer W. For example, the processes may be performed before the carrying-in process (see step S101 in FIG. 4) of the wafer W.

Moreover, the processes at steps S111, S112, and S114 to S118 in FIG. 5 may be performed at a periodic timing, during a period when the substrate processing using SPM is not taking place. That is, the controller 18 starts the processes from step S111 at a periodic timing, and if the temperature of sulfuric acid is within the allowable range (Yes at step S112) and when the dummy dispensing process is finished (step S118), returns the process to step S111.

### Second Embodiment

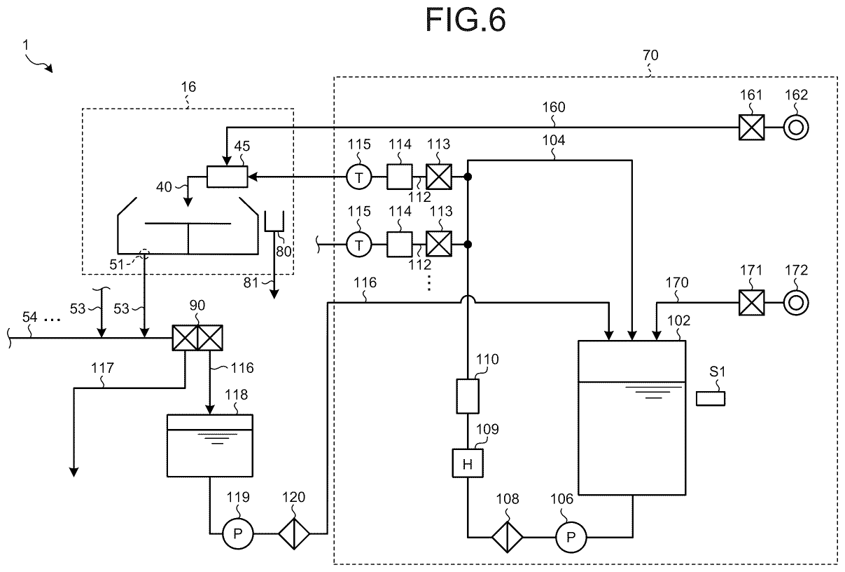

Next, a specific configuration example of a processing liquid supply system in the substrate processing system 1 according to the second embodiment will be described with reference to FIG. 6. FIG. 6 is a diagram illustrating a specific configuration example of a processing liquid supply system in the substrate processing system 1 according to the second embodiment. In the following description, parts that are the same as those already described are given the same reference numerals as those already described, and duplicate explanation will be omitted.

Each branch route 112 illustrated in FIG. 6 includes a temperature regulating unit 114. The temperature regulating unit 114 is provided on the downstream side of the valve 113 in the branch route 112. The temperature regulating unit 114 is controlled by the controller 18, and regulates the temperature of the sulfuric acid in the branch route 112. Specifically, the temperature regulating unit 114 regulates the temperature of the sulfuric acid flowing through the branch route 112 or the sulfuric acid retained in the branch route 112. A heater with a heating function can be used as the temperature regulating unit 114. A device with both heating function and cooling function may also be used as the temperature regulating unit 114. Moreover, a plurality of the temperature regulating units 114 may be provided in the branch route 112.

Although not illustrated in the example, another temperature regulating unit may also be provided in the hydrogen peroxide solution supply route 160. The other temperature regulating unit regulates the temperature of the hydrogen peroxide solution in the hydrogen peroxide solution supply route 160. Specifically, the other temperature regulating unit regulates the temperature of the hydrogen peroxide solution flowing through the hydrogen peroxide solution supply route 160 or the hydrogen peroxide solution retained in the hydrogen peroxide solution supply route 160.

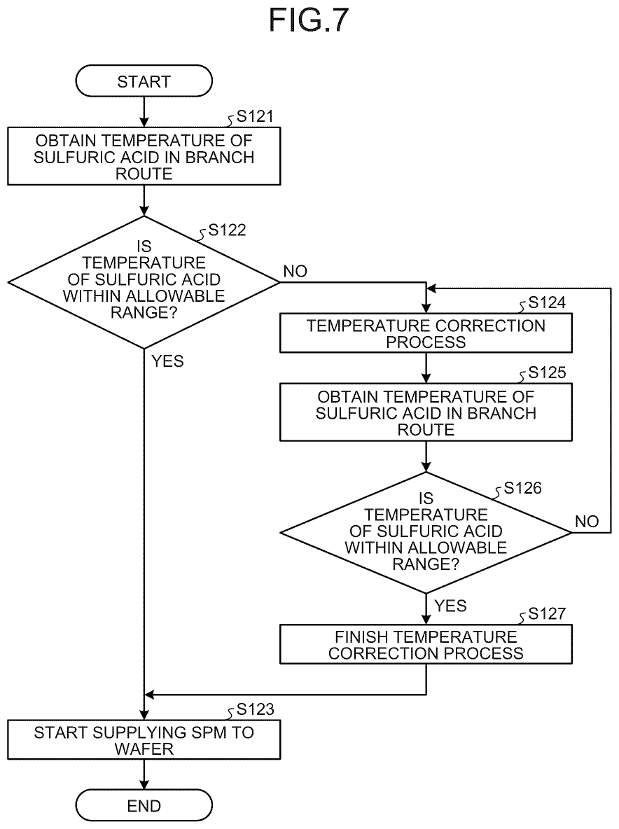

Next, a specific procedure of an SPM supply process according to the second embodiment will be described with reference to FIG. 7. FIG. 7 is a flowchart illustrating a specific procedure of an SPM supply process according to the second embodiment. In FIG. 7, the processes at steps S121 to S123 are the same as those at steps S111 to S113 in FIG. 5. Hence, the description thereof will be omitted.

If the temperature of the sulfuric acid obtained from the temperature detection unit 115 is not within the allowable range (No at step S122), the controller 18 controls the temperature regulating unit 114 to perform a temperature correction process of correcting the temperature of the sulfuric acid in the branch route 112 (step S124). Consequently, the relatively low-temperature sulfuric acid retained in the branch route 112 is heated. Consequently, the temperature of the sulfuric acid in the branch route 112 rises and falls within the allowable range. As a result, it is possible to suppress variations in the temperature of the sulfuric acid before being mixed by the mixing unit 45.

Subsequently, the controller 18 obtains the temperature of the sulfuric acid in the branch route 112 from the temperature detection unit 115 (step S125). Then, the controller 18 determines whether the temperature of the sulfuric acid obtained from the temperature detection unit 115 is within the allowable range (step S126).

If the temperature of sulfuric acid is not within the allowable range (No at step S126), the controller 18 returns the process to step S124. On the other hand, if the temperature of sulfuric acid is within the allowable range (Yes at step S126), the controller 18 stops the temperature regulating unit 114 and finishes the temperature correction process (step S127). Consequently, it is possible to finish the temperature correction process at a suitable timing, and suppress variations in the temperature of the sulfuric acid before being mixed by the mixing unit 45, while suppressing an increase in the consumption power of the temperature regulating unit 114 in the temperature correction process.

In the example in FIG. 7, the controller 18 starts supplying the SPM to the wafer W, when the temperature of the sulfuric acid in the branch route 112 is within the allowable range. However, the starting conditions for supplying the SPM are not limited thereto. For example, the controller 18 may also determine whether the temperature of the hydrogen peroxide solution in the hydrogen peroxide solution supply route 160 is within the allowable range, and start supplying the SPM to the wafer W, when the temperature of the hydrogen peroxide solution is within the allowable range. For example, the allowable temperature range of the hydrogen peroxide solution is a predetermined temperature range around the ambient temperature (25° C.). Moreover, for example, the controller 18 may start supplying the SPM to the wafer W, when the temperature of sulfuric acid in the branch route 112 and the temperature of hydrogen peroxide solution in the hydrogen peroxide solution supply route 160 are each within the allowable range.

The processes at steps S121, S122, and S124 to S127 in FIG. 7 may be performed at any time prior to when the controller 18 starts supplying the SPM to the wafer W. For example, the processes may be performed before the carrying-in process (see step S101 in FIG. 4) of the wafer W.

Moreover, the processes at steps S121, S122, and S124 to S127 in FIG. 7 may be performed at a periodic timing, during a period when the substrate processing using SPM is not taking place. That is, the controller 18 starts the processes from step S121 at a periodic timing, and if the temperature of sulfuric acid is within the allowable range (Yes at step S122) and when the temperature correction process is finished (step S127), returns the process to step S121.

Moreover, the temperature correction process at step S124 in FIG. 7 may be performed in parallel with the dummy dispensing process at step S115 in FIG. 5.

### Third Embodiment

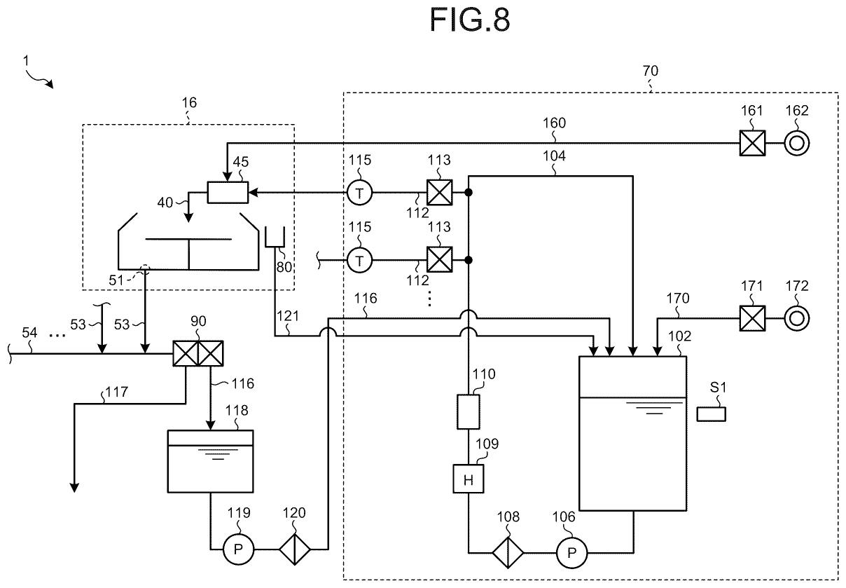

Next, a specific configuration example of a processing liquid supply system in the substrate processing system 1 according to the third embodiment will be described with reference to FIG. 8. FIG. 8 is a diagram illustrating a specific configuration example of a processing liquid supply system in the substrate processing system 1 according to the third embodiment. In the following description, parts that are the same as those already described are given the same reference numerals as those already described, and duplicate explanation will be omitted.

The substrate processing system 1 illustrated in FIG. 8 includes a collection route 121 instead of the discharge route 81 in FIG. 3. One end of the collection route 121 is connected to the accommodation unit 80, and the other end is connected to the retaining tank 102. The collection route 121 returns the sulfuric acid discharged from the nozzle 40 to the accommodation unit 80 as a processing liquid during the dummy dispensing process, to the retaining tank 102. Consequently, the substrate processing system 1 can collect and reuse the sulfuric acid by returning the sulfuric acid during the dummy dispensing process, to the retaining tank 102 via the collection route 121. Hence, it is possible to suppress the consumption amount of sulfuric acid.

As described above, the substrate processing apparatus (as an example, the substrate processing system 1) according to the embodiment includes the substrate processing unit (as an example, the processing unit 16), the first route (as an example, the branch route 112), the second route (as an example, the hydrogen peroxide solution supply route 160), the first opening/closing valve (as an example, the valve 113), the second opening/closing valve (as an example, the valve 161), the temperature detection unit (as an example, the temperature detection unit 115), and the controller (as an example, the controller 18). The substrate processing unit processes a substrate, by generating a mixed solution (as an example, the SPM) by mixing the first processing liquid (as an example, the sulfuric acid) and the second processing liquid (as an example, the hydrogen peroxide solution), and by supplying the generated mixed solution to the substrate (as an example, the wafer W). The first route supplies the first processing liquid to the substrate processing unit. The second route supplies the second processing liquid to the substrate processing unit. The first opening/closing valve opens and closes the first route. The second opening/closing valve opens and closes the second route. The temperature detection unit is provided on at least one of the first route and the second route, and detects the temperature of the processing liquid in at least one of the routes. The controller determines whether the temperature of the processing liquid detected using the temperature detection unit is within the allowable range, before the substrate processing unit starts supplying the mixed solution to the substrate. The controller starts supplying the mixed solution to the substrate by opening the first opening/closing valve and the second opening/closing valve, when the temperature of the processing liquid is within the allowable range. Consequently, with the substrate processing apparatus according to the embodiment, it is possible to suppress variations in the processing results of the substrates, in the substrate processing using a mixed solution.

Moreover, the substrate processing unit may include the mixing unit (as an example, the mixing unit 45), the nozzle (as an example, the nozzle 40), and the accommodation unit (as an example, the accommodation unit 80). The mixing unit is connected to the first route and the second route, and generates a mixed solution by mixing the first processing liquid from the first route and the second processing liquid from the second route. The nozzle discharges the mixed solution generated by the mixing unit to the substrate. The accommodation unit accommodates the nozzle to standby. If the temperature of the processing liquid is not within the allowable range, the controller may move the nozzle to the accommodation unit to standby. The controller may also perform a dummy dispensing process of opening a valve corresponding to at least one of the routes between the first opening/closing valve and the second opening/closing valve, and discharging the processing liquid to the accommodation unit from the nozzle, while the nozzle is standing by. Consequently, with the substrate processing apparatus according to the embodiment, it is possible to suppress variations in the temperature of the processing liquid (as an example, the sulfuric acid) before being mixed by the mixing unit.

Moreover, the controller may determine whether the temperature of the processing liquid detected using the temperature detection unit is within the allowable range, after the dummy dispensing process is started. The controller may close the valve and finish the dummy dispensing process, when the temperature of the processing liquid is within the allowable range. Consequently, with the substrate processing apparatus according to the embodiment, it is possible to suppress the consumption amount of the processing liquid (as an example, the sulfuric acid) in the dummy dispensing process.

Furthermore, the controller may move the nozzle to a position where the mixed solution can be supplied to the substrate from the accommodation unit, and start supplying the mixed solution to the substrate by opening the first opening/closing valve and the second opening/closing valve, after the dummy dispensing process is finished. Consequently, with the substrate processing apparatus according to the embodiment, it is possible to suppress variations in the processing results of the substrates, in the substrate processing using a mixed solution.

Still furthermore, the mixing unit may generate the mixed solution by mixing the first processing liquid supplied from the retaining tank (as an example, the retaining tank 102) that retains the first processing liquid via the first route, and the second processing liquid. The substrate processing apparatus according to the embodiment may further include the collection route (as an example, the collection route 121) that returns the first processing liquid discharged from the nozzle to the accommodation unit as the processing liquid during the dummy dispensing process, to the retaining tank. Consequently, with the substrate processing apparatus according to the embodiment, it is possible to collect and reuse the sulfuric acid, and suppress the consumption amount of sulfuric acid.

Still furthermore, the substrate processing apparatus according to the embodiment may further include the temperature regulating unit (as an example, the temperature regulating unit 114) provided on at least one of the first route and the second route. If the temperature of the processing liquid in at least one of the routes is not within the allowable range, the controller may control the temperature regulating unit to perform a temperature correction process for correcting the temperature of the processing liquid. Consequently, with the substrate processing apparatus according to the embodiment, it is possible to suppress variations in the temperature of the processing liquid (as an example, the sulfuric acid) before being mixed by the mixing unit.

Still furthermore, the controller may also determine whether the temperature of the processing liquid in at least one of the routes detected using the temperature detection unit is within the allowable range, after the temperature correction process is started. The controller may stop the temperature regulating unit and finish the temperature correction process, when the temperature of the processing liquid in at least one of the routes is within the allowable range. Consequently, with the substrate processing apparatus according to the embodiment, it is possible to suppress variations in the temperature of the processing liquid (as an example, the sulfuric acid) before being mixed by the mixing unit, while suppressing an increase in the consumption power of the temperature regulating unit in the temperature correction process.

Still furthermore, the controller may start supplying the mixed solution to the substrate by opening the first opening/closing valve and the second opening/closing valve, after the temperature correction process is finished. Consequently, with the substrate processing apparatus according to the embodiment, it is possible to suppress variations in the processing results of the substrates, in the substrate processing using a mixed solution.

It should be noted that the embodiments disclosed this time are exemplary in all respects and are not restrictive. Indeed, the embodiments described above may be embodied in various forms. Moreover, the above exemplary embodiments may be omitted, replaced, or modified in various forms without departing from the scope and spirit of the appended claims.

According to the present disclosure, it is possible to suppress variations in the processing results of the substrates.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing apparatus, comprising:
a substrate processing unit that processes a substrate, by generating a mixed solution by mixing a first processing liquid and a second processing liquid, and by supplying the generated mixed solution to the substrate;
a first route that supplies the first processing liquid to the substrate processing unit;
a second route that supplies the second processing liquid to the substrate processing unit;
a first opening/closing valve that opens and closes the first route;
a second opening/closing valve that opens and closes the second route;
a temperature detection unit provided on at least one of the first route and the second route, and that detects temperature of a processing liquid in at least one of the routes; and
a controller that controls each unit, wherein
the controller
determines whether the temperature of the processing liquid detected using the temperature detection unit is within an allowable range, before the substrate processing unit starts supplying the mixed solution to the substrate, and
when the temperature of the processing liquid is within the allowable range, starts supplying the mixed solution to the substrate by opening the first opening/closing valve and the second opening/closing valve.

2. The substrate processing apparatus according to claim 1, wherein
the substrate processing unit includes
a mixing unit connected to the first route and the second route, and that generates a mixed solution by mixing the first processing liquid from the first route and the second processing liquid from the second route,
a nozzle that discharges the mixed solution generated by the mixing unit to the substrate, and
an accommodation unit that accommodates the nozzle to standby, and
the controller,
when the temperature of the processing liquid is not within the allowable range, moves the nozzle to the accommodation unit to standby, and
performs a dummy dispensing process of discharging the processing liquid to the accommodation unit from the nozzle by opening a valve corresponding to at least one of the routes between the first opening/closing valve and the second opening/closing valve, while the nozzle is standing by.

3. The substrate processing apparatus according to claim 2, wherein
the controller
determines whether the temperature of the processing liquid detected using the temperature detection unit is within an allowable range, after the dummy dispensing process is started, and
when the temperature of the processing liquid is within the allowable range, finishes the dummy dispensing process by closing the valve.

4. The substrate processing apparatus according to claim 3, wherein
the controller
moves the nozzle from the accommodation unit to a position cable of supplying the mixed solution to the substrate, after the dummy dispensing process is finished, and
starts supplying the mixed solution to the substrate by opening the first opening/closing valve and the second opening/closing valve.

5. The substrate processing apparatus according to claim 2, wherein
the mixing unit
generates a mixed solution by mixing the first processing liquid supplied from a retaining tank that retains the first processing liquid via the first route and the second processing liquid, the substrate processing apparatus, further comprising:
a collection route that returns the first processing liquid discharged from the nozzle to the accommodation unit as the processing liquid during the dummy dispensing process, to the retaining tank.

6. The substrate processing apparatus according to claim 1, further comprising:
a temperature regulating unit provided on at least one of the first route and the second route, wherein
the controller
when the temperature of the processing liquid in at least one of the routes is not within the allowable range, controls the temperature regulating unit to perform a temperature correction process for correcting the temperature of the processing liquid.

7. The substrate processing apparatus according to claim 6, wherein
the controller
determines whether the temperature of the processing liquid in at least one of the routes detected using the temperature detection unit is within an allowable range, after the temperature correction process is started, and
when the temperature of the processing liquid in at least one of the routes is within the allowable range, finishes the temperature correction process by stopping the temperature regulating unit.

8. The substrate processing apparatus according to claim 7, wherein
the controller
starts supplying the mixed solution to the substrate by opening the first opening/closing valve and the second opening/closing valve, after the temperature correction process is finished.

9. A substrate processing method in a substrate processing apparatus that includes
a substrate processing unit that processes a substrate, by generating a mixed solution by mixing a first processing liquid and a second processing liquid, and by supplying the generated mixed solution to the substrate;
a first route that supplies the first processing liquid to the substrate processing unit;
a second route that supplies the second processing liquid to the substrate processing unit;
a first opening/closing valve that opens and closes the first route;
a second opening/closing valve that opens and closes the second route; and
a temperature detection unit provided on at least one of the first route and the second route, and that detects temperature of a processing liquid in at least one of the routes, the substrate processing method, comprising:
determining whether the temperature of the processing liquid detected using the temperature detection unit is within an allowable range, before the substrate processing unit starts supplying the mixed solution to the substrate, and
starting to supply the mixed solution to the substrate by opening the first opening/closing valve and the second opening/closing valve, when the temperature of the processing liquid is within the allowable range.
